(19) United States
(12) Patent Application Publication
(10) Pub. No.: US 2010/0229066 A1
(43) Pub. Date: Sep. 9, 2010

(54) CHECK MATRIX GENERATING METHOD

(75) Inventors: Wataru Matsumoto, Tokyo (JP); Rui Sakai, Chiyoda-ku (JP); Hideo Yoshida, Chiyoda-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/160,432

(22) PCT Filed: Jan. 5, 2007
(86) PCT No.: PCT/JP2007/050021

§ 371 Date: Oct. 16, 2008

(30) Foreign Application Priority Data
Jan. 10, 2006 (JP) 2006-003023

(51) Int. Cl. H03M 13/05; G06F 11/10

(52) U.S. Cl. 714/752; 714/E11.032

(57) ABSTRACT

An irregular parity check matrix is generated which has an LDGM structure in which a masking quasi-cyclic matrix and a matrix in which cyclic permutation matrices are arranged in a staircase manner are arranged in a predetermined location. A mask matrix capable of supporting a single encoding rate for making the regular quasi-cyclic matrix into an irregular quasi-cyclic matrix is generated. The irregular parity check matrix is masked using a generated mask matrix, and a parity check matrix is generated combining a masked irregular parity check matrix with a lower triangular matrix formed in a staircase manner to satisfy a single encoding rate.

### TECHNICAL FIELD

The present invention relates to an encoding technology in digital communications, in particular to a check-matrix generating method of generating a parity check matrix for low-density parity check (LDPC) codes, an encoding method of encoding predetermined data bits using the parity check matrix, and a communication apparatus.

### BACKGROUND ART

Hereinafter, a conventional communication system that employs LDPC codes as an encoding system will be explained. Here, a case in which quasi-cyclic (QC) codes (see Non-patent Document 1) are employed as one example of the LDPC codes will be explained.

First, a flow of encoding/decoding processing in the conventional communication system that employs the LDPC codes as the encoding system will be explained briefly.

An LDPC encoder in a communication apparatus on a transmission-side (it is called a transmission apparatus) generates a parity check matrix H by a conventional method that will be explained below. Further, the LDPC encoder generates, for example, a generator matrix G with K-row×N-column (K: data length, N: code length). Note that when the parity check matrix for LDPC is defined as H (M-row×N-column), the generator matrix G will be a matrix that satisfies GH^{T}=0 (T is a transposed matrix).

Thereafter, the LDPC encoder receives messages (m₁, m₂, . . . , m_{K}) with the data length K to generate a code C as represented by following Equation (1) using these messages and the generator matrix G, where H(c₁, c₂, . . . , c_{N})^{T}=0.

C=(m₁,m₂, . . . , m_{K})G=(c₁, c₂, . . . , c_{N}) (1)

A modulator in the transmission apparatus then performs digital modulation to the code C generated by the LDPC encoder according to a predetermined modulation system, such as binary phase shift keying (BPSK), quadrature phase shift keying (QPSK), multi-value quadrature amplitude modulation (QAM), and transmits a modulated signal x=(x₁, x₂, . . . , x_{N}) to a reception apparatus.

Meanwhile, in a communication apparatus on a reception-side (which is called a reception apparatus), a demodulator performs digital demodulation to a received modulated signal y=(y₁, y₂, . . . , y_{N}) according to the modulation system such as BPSK, QPSK, multi-value QAM, or the like, and an LDPC decoder in the reception apparatus further performs repetition decoding to demodulated results based on a “sum-product algorithm” to thereby output the decoded results (corresponding to the original messages m₁, m₂, . . . , m_{K}).

The conventional parity check-matrix generating method for the LDPC codes will now be explained concretely. As the parity check matrix for the LDPC codes, a following parity check matrix of QC codes is proposed, for example, in following Non-patent Document 1. The parity check matrix of the QC codes shown in FIG. 10 is a matrix in which cyclic permutation matrices (P=5) with p-row×p-column are arranged in a vertical direction (J=3) and in a horizontal direction (L=5).

Generally, a parity check matrix H_{QC} of the (J, L) QC codes with M (=pJ) rows×N (=pL) columns can be defined as following Equation (2). Incidentally, p is an odd prime number (other than 2), L is the number of cyclic permutation matrices in the parity check matrix H_{QC} in a transverse direction (column direction), and J is the number of cyclic permutation matrices in the parity check matrix H_{QC} in a longitudinal direction (row direction).

[Numerical Expression 1]

$${H}_{QC} = [ \begin{matrix}I ( {P}_{0 , 0} ) & I ( {P}_{0 , 1} ) & ⋮ & I ( {P}_{0 , L - 1} ) \\ I ( {P}_{1 , 0} ) & I ( {P}_{1 , 1} ) & ⋮ & I ( {P}_{1 , L - 1} ) \\ ⋮ & ⋮ & ⋱ & ⋮ \\ I ( {P}_{J - 1 , 0} ) & I ( {P}_{J - 1 , 1} ) & ⋮ & I ( {P}_{J - 1 , L - 1} )\end{matrix} ] \\ example \text{:} p = 5 , 1 ( 0 ) = [ \begin{matrix}1 & 0 & 0 & 0 & 0 \\ 0 & 1 & 0 & 0 & 0 \\ 0 & 0 & 1 & 0 & 0 \\ 0 & 0 & 0 & 1 & 0 \\ 0 & 0 & 0 & 0 & 1\end{matrix} ] \qquad ( 2 )$$

Where, in 0≦j≦J−1 and 0≦l≦L−1, I(p_{j,l}) are cyclic permutation matrices in which positions of a row index: r (0≦r≦P−1), and a column index: “(r+p_{j,l})mod p” are “1”, and other positions are “0”.

In addition, when the LDPC codes are designed, performance degradation generally occurs when there are many loops with a short length, and thus it is necessary to increase an internal diameter and to reduce the number of loops with the short length (loop 4, loop 6, or the like).

Incidentally, FIG. 11 is a view showing one example of the check matrix represented by a Tanner graph. In the binary parity check matrix H of {0,1} with M-row×N-column, nodes corresponding to each column are called bit nodes bₙ (1≦n≦N) (corresponding to circles in the figure), and nodes corresponding to each row are called check nodes cₘ (1≦m≦M) (corresponding to rectangles in the figure), and further, when there is “1” at an intersection of the row and the column of the check matrix, a bipartite graph in which the bit nodes and the check nodes are connected with branches is called the Tanner graph. In addition, the loop represents a closed loop that starts from a specific node (corresponding to circles and rectangles in the figure) and ends at that node as shown in FIG. 11, and the internal diameter means the minimum loop thereof. Moreover, a loop length is represented by the number of branches constituting the closed loop, and is simply represented as loop 4, loop 6, loop 8, . . . according to the length.

Meanwhile, in following Non-patent Document 1, a range of an internal diameter g in the parity check matrix H_{QC} of (J,L) QC-LDPC codes is given by “4≦g≦12 (where g is an even number)”. However, it is easy to avoid g=4 and, and it results in g≧6 in many cases.

Non-patent Document 1: M. Fossorier, “quasi-cyclic Low Density Parity Check Code”, ISIT2003, p. 150, Japan, Jun. 29-Jul. 4, 2003.

### DISCLOSURE OF INVENTION

### Problem to be Solved by the Invention

According to the conventional technology, however, a plurality of different check matrices is required to change encoding rates, so that there are problems that a memory amount is increased and a circuit becomes complicated.

### Means for Solving Problem

To solve the above problems, a check-matrix generating method according to the present invention is for generating a parity check matrix for a LDPC (low-density parity check) code, including a quasi-cyclic matrix generating step of generating a regular (weights of a row and a column are uniform) quasi-cyclic matrix in which cyclic permutation matrices are arranged in a row direction and a column direction and specific regularity is given to the cyclic permutation matrices; a step of obtaining an irregular parity check matrix having a LDGM (low-density generation matrix) structure in which a masking quasi-cyclic matrix and a matrix in which the cyclic permutation matrices are arranged in a staircase manner are arranged in a predetermined location; a mask-matrix generating step of generating a mask matrix capable of supporting a single encoding rate out of a plurality of encoding rates, for making the regular quasi-cyclic matrix into irregular (weights of a row and a column are nonuniform); and a check-matrix generating step including masking the regular parity check matrix using a generated mask matrix and generating a parity check matrix in which a masked irregular parity check matrix is combined with a lower triangular matrix formed in a staircase manner to satisfy a single encoding rate.

### EFFECT OF THE INVENTION

According to the present invention, only one check matrix is required to obtain a plurality of encoding rates for a certain data length, which allows a significant reduction of the circuit scale.

### BRIEF DESCRIPTION OF DRAWINGS

FIG. 1 is a block diagram showing a configuration of a communication system according to a first embodiment of the present invention.

FIG. 2 is a block diagram showing a detailed configuration of the communication system according to the first embodiment of the present invention.

FIG. 3 is a view showing a configuration of an irregular parity check matrix according to a second embodiment of the present invention.

FIG. 4 is a view for comparing performances between a code configuration method according to the first and the second embodiments and a code configuration method according to a third embodiment of the present invention.

FIG. 5 is a view for explaining the code configuration method according to the third embodiment of the present invention.

FIG. 6 is a view for explaining the code configuration method according to the third embodiment of the present invention.

FIG. 7 is a view showing a configuration of a parity check matrix according to the third embodiment of the present invention.

FIG. 8 is a view showing a configuration of a parity check matrix according to a fifth embodiment of the present invention.

FIG. 9 is a view showing a configuration of a parity check matrix according to a sixth embodiment of the present invention.

FIG. 10 is a view showing an example of the parity check matrix.

FIG. 11 is a view showing a check matrix in an LDPC encoding processing represented by a Tanner graph.

### EXPLANATIONS OF LETTERS OR NUMERALS

1 Transmission apparatus
2 Communication channel
3 Reception apparatus
11 LPDC encoder
12 Parity-check-matrix generator
13 Modulator
14 Demodulator
21 QC-LDPC check-matrix storage unit
22 Masking unit

### BEST MODE(S) FOR CARRYING OUT THE INVENTION

### First Embodiment

Embodiments of a check-matrix generating method according to the present invention will be explained in detail below based on the drawings. It is noted that the present invention is not limited by these embodiments.

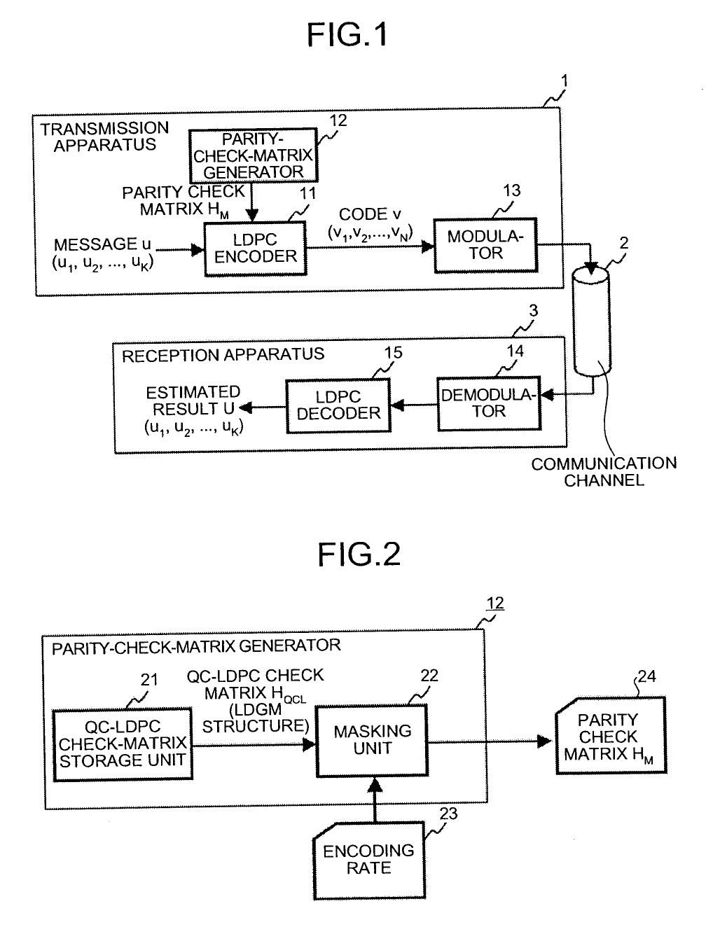

FIG. 1 is a diagram showing a configuration example of a communication system including a transmission apparatus and a reception apparatus according to a first embodiment of the present invention. In the figure, a transmission apparatus 1 includes an LDPC encoder 11, a parity-check-matrix generator 12, and a modulator 13. A communication channel 2 is an information transmission channel, typically such as a wireless transmission network and an optical transmission network. A reception apparatus 3 includes a demodulator 14 and an LDPC decoder 15.

Incidentally, it is not always necessary for the communication channel 2 to enable bidirectional communications, and thus, for example, the configuration may be such that information is transmitted by directly transferring a storage medium. In this case, the transmission apparatus 1 is a device on a side of writing information to the storage medium, and the reception apparatus 2 corresponds to a device on a side of reading information from the storage medium.

Here, a flow of encoding processing and decoding processing in the communication system shown in FIG. 1 will be explained briefly.

The LDPC encoder 11 of the transmission apparatus 1 receives a message u=(u₁, u₂, . . . , uₖ) with an data length K, and encodes the message u using a parity check matrix H_{M} output from the parity-check-matrix generator 12 to generate a code v with a length N that satisfies Equation (3).

v={(v₁,v₂, . . . , v_{N})εGF(2)|(v₁,v₂, . . . , v_{N})H_{M}^{T}=0} (3)

Here, the parity check matrix H_{M} output by the parity-check-matrix generator 12 is a parity check matrix with M-row×N-column to which masking processing is performed based on a predetermined masking rule.

The modulator 13 digital-modulates the code v generated by the LDPC encoder 12 according to a predetermined modulation system, such as BPSK, QPSK, and multi-value QAM, and generates a modulated signal x=(x₁, x₂, . . . , x_{N}). The modulated signal x is transmitted via the communication channel 2, to be received as a modulated signal y=(y₁, y₂, y_{N}) by the reception apparatus 3.

In the reception apparatus 3, the demodulator 14 performs digital demodulation on the received modulated signal y according to a modulation system employed by the transmission apparatus side, such as the BPSK, QPSK, and multi-value QAM. The demodulated result is input to the LDPC decoder 15. The LPDC decoder 15 performs repetition decoding on the demodulated result to thereby output an estimated result U (corresponding to the original message u=(u₁, u₂, . . . , uₖ)).

In this case, in a transmission/reception system based on a conventional LDPC encoding decoding system, data bits are encoded by using the generator matrix G to obtain the data length K and the code length N. However, the communication system according to the embodiment of the present invention has a feature that the encoding is performed by using the parity check matrix.

The generating method of the check matrix H_{M} in the parity-check-matrix generator 12 will be explained in detail below. FIG. 2 is a block diagram showing a detailed configuration of the parity-check-matrix generator 12. In the figure, a quasi-cyclic LDPC (QC-LDPC) check-matrix storage unit 21 is a storage device or a circuit or a medium that stores therein a QC-LDPC check matrix H_{QCL} (hereinafter, “check matrix H_{QCL}”) with an LDGM structure.

A masking unit 22 obtains the check matrix H_{QCL} from the QC-LDPC check-matrix storage unit 21, performs masking on the check matrix H_{QCL} according to an encoding rate 23, and outputs an irregular (singular, a weight distribution is nonuniform) parity check matrix H_{M} 24. A plurality of encoding rates is assumed as the encoding rate 23. More specifically, the communication system according to the present embodiment has a feature that a common check matrix H_{QCL} is adapted to the assumed encoding rates to generate parity check matrices H_{M} according to the respective encoding rates.

The structure of the check matrix H_{QCL} stored in the QC-LDPC check-matrix storage unit 21 will be explained next.

If the check matrix H_{QCL} (=[h_{m,n}]) is formed of M (=p_{J}) rows×N (=p_{L}+p_{J}) columns, it is defined as Equation (4).

[Numerical Expression 2]

$${H}_{QCL} := [ \begin{matrix}I ( {P}_{0 , 0} ) & I ( {P}_{0 , 1} ) & ⋯ & I ( {P}_{0 , L - 1} ) & I ( 0 ) & 0 & ⋯ & ⋯ & ⋯ & ⋯ & ⋯ & 0 \\ I ( {P}_{1 , 0} ) & I ( {P}_{1 , 1} ) & ⋯ & I ( {P}_{1 , L - 1} ) & I ( 0 ) & I ( 0 ) & 0 & ⋱ & ⋱ & ⋱ & ⋱ & ⋮ \\ ⋮ & ⋮ & ⋮ & ⋮ & 0 & ⋱ & ⋱ & ⋱ & ⋱ & ⋱ & ⋱ & ⋮ \\ I ( {P}_{J \text{/} 2 - 1 , 0} ) & I ( {P}_{J \text{/} 2 - 1 , 2} ) & ⋯ & I ( {P}_{J \text{/} 2 - 1 , L - 1} ) & ⋮ & ⋱ & I ( 0 ) & I ( 0 ) & 0 & ⋱ & ⋱ & ⋮ \\ ⋮ & ⋮ & ⋮ & ⋮ & I ( 0 ) & 0 & ⋯ & 0 & I ( 0 ) & 0 & ⋱ & ⋮ \\ ⋮ & ⋮ & ⋮ & ⋮ & 0 & I ( 0 ) & 0 & ⋱ & ⋱ & I ( 0 ) & ⋱ & ⋮ \\ ⋮ & ⋮ & ⋮ & ⋮ & ⋮ & ⋱ & ⋱ & ⋱ & ⋱ & ⋱ & ⋱ & 0 \\ I ( {P}_{J - 1 , 0} ) & I ( {P}_{J - 1 , 2} ) & ⋮ & I ( {P}_{J - 1 , L - 1} ) & 0 & ⋯ & 0 & I ( 0 ) & 0 & ⋯ & 0 & I ( 0 )\end{matrix} ] \qquad ( 4 )$$

Here, h_{m,n} represents an element (matrix component) at a row index m and a column index n in the check matrix H_{QCL}. Further, p_{J} is provided with p_{J}=K×M if the number of data bits is K and a minimum encoding rate assumed as the encoding rate 23 is 1/M, and p_{L} is provided with p_{L}=K×(M+1).

Additionally, in 0≦j≦J−1 and 0≦l≦L−1, I(p_{j,l}) are regular cyclic permutation matrices of p×p in which elements of a row index r (where 0≦r≦p−1) and a column index “(r+p_{j,l})mod p” are “1” and other elements are “0”. For example, I(1) can be represented as Equation (5).

[Numerical Expression 3]

$$I ( 1 ) = [ \begin{matrix}0 & 1 & 0 & ⋯ & 0 \\ 0 & 0 & 1 & ⋯ & 0 \\ ⋯ & ⋯ & ⋯ & ⋯ & ⋯ \\ 0 & 0 & 0 & ⋯ & 1 \\ 1 & 0 & 0 & ⋯ & 0\end{matrix} ] \qquad ( 5 )$$

Further, a prime number other than 2 is generally selected as p. However, if p is variable, an odd number may be selected. If p is set to be variable while remaining as the prime number, the prime number needs to be stored in the memory, however, the case of an odd number has an advantage that the memory is not needed. If p is an odd number and even if performance may be degraded upon puncture of a high encoding rate, there is only a slight amount of degradation thereof as compared with the case where p is set to be a prime number.

In the following explanation, in the component of the check matrix, a portion corresponding to data bits or submatrices through columns equal to the number of data bits is called “left-hand side matrix”. Namely, if the number of data bits is K, submatrices obtained by extracting only a column component from a 1st column to a K-th column correspond to the left-hand side matrix. Further, in the component of the parity check matrix, a portion corresponding to parity bits or submatrices obtained by extracting only a column component except the left-hand side matrix is called “right-hand side matrix”.

Also, in the following explanation, the left-hand side indicates a component corresponding to the data bits, while the right-hand side indicates a component corresponding to the parity bits.

In the check matrix H_{QCL} as shown in Equation (4), the left-hand side matrix is a quasi-cyclic matrix H_{QCL} that is the same as the parity check matrix of QC codes shown by Equation (2). The right-hand side component of the check matrix H_{QCL} is a matrix H_{T} (staircase-like lower triangular matrix) in which I(0) are arranged in a staircase manner as shown in Equation (6).

[Numerical Expression 4]

$${H}_{T} := [ \begin{matrix}I ( 0 ) & 0 & ⋯ & ⋯ & ⋯ & ⋯ & ⋯ & 0 \\ I ( 0 ) & I ( 0 ) & 0 & ⋱ & ⋱ & ⋱ & ⋱ & ⋮ \\ 0 & ⋱ & ⋱ & ⋱ & ⋱ & ⋱ & ⋱ & ⋮ \\ ⋮ & ⋱ & I ( 0 ) & I ( 0 ) & 0 & ⋱ & ⋱ & ⋮ \\ I ( 0 ) & 0 & ⋯ & 0 & I ( 0 ) & 0 & ⋱ & ⋮ \\ 0 & I ( 0 ) & 0 & ⋱ & ⋱ & I ( 0 ) & ⋱ & ⋮ \\ ⋮ & ⋱ & ⋱ & ⋱ & ⋱ & ⋱ & ⋱ & 0 \\ 0 & ⋯ & 0 & I ( 0 ) & 0 & ⋯ & 0 & I ( 0 )\end{matrix} ] \qquad ( 6 )$$

It is noted that the portion of the matrix H_{T} may be arranged as H_{D} shown in Equation (7).

[Numerical Expression 5]

$${H}_{D} := [ \begin{matrix}I ( 0 ) & 0 & ⋯ & ⋯ & 0 \\ I ( 0 ) & I ( 0 ) & 0 & ⋱ & ⋮ \\ 0 & ⋱ & ⋱ & ⋱ & ⋮ \\ ⋮ & ⋱ & I ( 0 ) & I ( 0 ) & 0 \\ 0 & ⋯ & 0 & I ( 0 ) & I ( 0 )\end{matrix} ] \qquad ( 7 )$$

The cyclic permutation matrices arranged in the staircase manner in Equation (6) and Equation (7) may use arbitrary I(s|sε[0, p−1]) in addition to I(0), or may use a combination of different I(s1) and I(s2) (where s1, s2ε[0, p−1] and s1#s2).

Here, the LDGM structure indicates a structure, as the matrix shown in Equation (4), in which the cyclic permutation matrices are arranged so that the component (right-hand side component) of the matrix corresponding to the parity bits is formed into a lower triangular matrix. Encoding can be achieved easily by using this structure without using the generator matrix G. For example, when the systematic code v is represented as following Equation (8), and the data message u=(u₁, u₂, . . . , uₖ) is given, parity elements pₘ=(p₁, p₂, . . . , p_{M}) are generated so that “H_{QCL}.v^{T}=0” may be satisfied, namely as following Equation (9).

v=(v₁, v₂, . . . v_{K}, v_{K+1}, v_{K+2}, . . . , v_{N})=(u₁, u₂, . . . , u_{K}, p₁, p₂, . . . , p_{M}) (8)

where N=K+M.

[Numerical Expression 6]

$${P}_{m} = {\sum }_{n = 1}^{K + m - 1} {v}_{n} {h}_{m , n} , 1 \leq m \leq M , 1 \leq n \leq N \qquad ( 9 )$$

Further, in the communication system according to the present embodiment, specific regularity is provided in the quasi-cyclic matrix H_{QC} portion on the left-hand side of the check matrix H_{QCL} defined in Equation (4). Specifically, to define a component of cyclic permutation matrices I(p_{j,l}) with p-row×p-column arranged at a row index j (=0, 1, 2, . . . , J−1) and a column index l (=0, 1, 2, . . . , L−1) in the quasi-cyclic matrix H_{QC} portion, a component of the cyclic permutation matrices I(p_{j,l}) is defined so that p_{j,l} is determined by Equation (10) or Equation (11) while setting p_{0,1} to an arbitrary integer.

p_{j,l}=p_{0,l}(j+1)mod p (10)

p_{j,l}=((p−p_{0,l}(j+1))mod p (11)

The above is the structure of the check matrix H_{QCL} stored in the QC-LDPC check-matrix storage unit 21.

Subsequently, the mask processing for the check matrix H_{QCL} performed in the masking unit 22 will be explained.

For example, the left-hand side matrix of H_{QCL} as shown in Equation (4) represents the quasi-cyclic matrix H_{QCL} of J×L as shown in Equation (12).

[Numerical Expression 7]

$${H}_{QC} := [ \begin{matrix}I ( {P}_{0 , 0} ) & I ( {P}_{0 , 1} ) & ⋯ & I ( {P}_{0 , L - 1} ) \\ I ( {P}_{1 , 0} ) & I ( {P}_{1 , 1} ) & ⋯ & I ( {P}_{1 , L - 1} ) \\ ⋮ & ⋮ & ⋮ & ⋮ \\ I ( {P}_{J - 1 , 0} ) & I ( {P}_{J - 1 , 1} ) & ⋯ & I ( {P}_{J - 1 , L - 1} )\end{matrix} ] \qquad ( 12 )$$

Assuming that a mask matrix Z (=[z_{j,l}]) is defined as a matrix with J-row×L-column on GF(2), the matrix H_{MQC} after the mask processing can be represented as Equation (13) if a predetermined rule described below is applied.

[Numerical Expression 8]

$${H}_{MQC} = Z ⊗ {H}_{QC} = [ \begin{matrix}{z}_{0 , 0} I ( {P}_{0 , 0} ) & {z}_{0 , 1} I ( {P}_{0 , 1} ) & ⋯ & {z}_{0 , L - 1} I ( {P}_{0 , L - 1} ) \\ {z}_{1 , 0} I ( {P}_{1 , 0} ) & {z}_{1 , 1} I ( {P}_{1 , 1} ) & ⋯ & {z}_{1 , L - 1} I ( {P}_{1 , L - 1} ) \\ ⋮ & ⋮ & ⋮ & ⋮ \\ {z}_{J - 1 , 0} I ( {P}_{J - 1 , 0} ) & {z}_{J - 1 , 1} I ( {P}_{J - 1 , 1} ) & ⋯ & {z}_{J - 1 , L - 1} I ( {P}_{J - 1 , L - 1} )\end{matrix} ] \qquad ( 13 )$$

It is noted that z in Equation (13) is defined as shown in Equation (14).

[Numerical Expression 9]

$${z}_{j , l} I ( {P}_{j , l} ) = \{ \begin{matrix}I ( {p}_{j , l} ) & \begin{matrix}for & {z}_{j , l} = & 1\end{matrix} \\ 0 & \begin{matrix}for & {z}_{j , l} = & 0\end{matrix}\end{matrix} \qquad ( 14 )$$

The zero-matrix in Equation (14) is a zero-matrix with p-row×p-column. Additionally, the matrix H_{MQC} is a matrix in which the quasi-cyclic matrix H_{QC} is masked with 0-elements of the mask matrix Z, and the weight distribution is nonuniform (irregular), while a distribution of the cyclic permutation matrices of the matrix H_{MQC} is the same as a degree distribution of the mask matrix Z.

Note that a weight distribution of the mask matrix Z when the weight distribution of H_{MQC} is nonuniform shall be determined by a predetermined density evolution method as will be below described. For example, if the number of data bits is set as K=32 and the encoding rate 23 is provided as ⅓, it is only necessary to prepare the mask matrix with 64-row×32-column. Such a mask matrix as above can be represented as Equation (15) based on a column degree distribution by the density evolution method using a mask matrix Z^{A} corresponding to an encoding rate ½.

[Numerical Expression 10]

$$Z = [ \frac{{Z}^{A}}{{Z}^{A} ( 1 \text{:} 32 , 2 \text{:} 5 ) {Z}^{A} ( 1 \text{:} 32 , 1 ) {Z}^{A} ( 1 \text{:} 32 , 7 \text{:} 16 ) {0}_{32 \times 15}} ] \qquad ( 15 )$$

In Equation (15), [ ] represents a matrix, and this means that the component above the bar (horizontal line) in [ ] is the same as the component of Z^{A}.

As explained above, Z^{A} is the mask matrix corresponding the encoding rate ½, and is as shown in, for example, Equation (16).

[Numerical Expression 11]

$${Z}^{A} = [ \begin{matrix}1 & 1 & 0 & 0 & 0 & 0 & 0 & 0 & 0 & 0 & 0 & 1 & 0 & 0 & 0 & 0 & 1 & 0 & 0 & 0 & 0 & 0 & 0 & 0 & 0 & 0 & 0 & 0 & 1 & 0 & 0 & 0 \\ 0 & 0 & 1 & 0 & 1 & 0 & 0 & 1 & 0 & 0 & 0 & 0 & 0 & 0 & 0 & 0 & 0 & 0 & 0 & 0 & 0 & 1 & 0 & 0 & 1 & 0 & 0 & 0 & 0 & 0 & 0 & 0 \\ 0 & 1 & 0 & 1 & 0 & 1 & 0 & 0 & 0 & 0 & 0 & 0 & 0 & 0 & 1 & 0 & 0 & 0 & 0 & 1 & 0 & 0 & 0 & 0 & 0 & 0 & 0 & 0 & 0 & 0 & 0 & 1 \\ 1 & 1 & 0 & 0 & 0 & 0 & 1 & 0 & 0 & 0 & 0 & 0 & 0 & 0 & 0 & 0 & 0 & 0 & 1 & 0 & 0 & 0 & 0 & 0 & 1 & 0 & 0 & 0 & 1 & 0 & 0 & 0 \\ 1 & 0 & 1 & 0 & 1 & 0 & 0 & 0 & 0 & 0 & 0 & 1 & 0 & 0 & 0 & 0 & 0 & 0 & 0 & 0 & 1 & 0 & 1 & 0 & 0 & 0 & 0 & 0 & 0 & 0 & 0 & 0 \\ 0 & 0 & 0 & 1 & 1 & 0 & 0 & 0 & 0 & 0 & 1 & 0 & 0 & 0 & 0 & 0 & 0 & 1 & 0 & 0 & 0 & 0 & 0 & 1 & 0 & 0 & 0 & 0 & 0 & 0 & 0 & 0 \\ 0 & 1 & 0 & 0 & 1 & 0 & 0 & 0 & 0 & 0 & 0 & 0 & 1 & 0 & 0 & 0 & 1 & 0 & 0 & 1 & 0 & 0 & 0 & 0 & 0 & 0 & 0 & 0 & 0 & 0 & 1 & 0 \\ 0 & 1 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 & 0 & 1 & 0 & 0 & 0 \\ 1 & 0 & 0 & 1 & 0 & 0 & 0 & 0 & 1 & 0 & 0 & 0 & 0 & 0 & 0 & 1 & 0 & 0 & 0 & 0 & 0 & 0 & 0 & 0 & 0 & 1 & 0 & 0 & 0 & 0 & 0 & 0 \\ 1 & 1 & 0 & 1 & 1 & 0 & 0 & 0 & 0 & 0 & 0 & 1 & 0 & 0 & 0 & 0 & 1 & 1 & 0 & 0 & 0 & 0 & 0 & 0 & 0 & 0 & 0 & 0 & 0 & 0 & 0 & 1 \\ 0 & 1 & 1 & 0 & 0 & 0 & 1 & 0 & 0 & 0 & 0 & 0 & 0 & 0 & 1 & 0 & 0 & 0 & 0 & 0 & 0 & 0 & 0 & 0 & 0 & 0 & 0 & 0 & 0 & 0 & 1 & 0 \\ 1 & 0 & 0 & 1 & 0 & 0 & 0 & 0 & 0 & 0 & 0 & 0 & 0 & 1 & 0 & 0 & 0 & 0 & 0 & 0 & 0 & 1 & 0 & 1 & 0 & 0 & 0 & 0 & 0 & 0 & 0 & 0 \\ 1 & 1 & 0 & 0 & 0 & 0 & 0 & 0 & 1 & 0 & 0 & 0 & 0 & 0 & 0 & 0 & 1 & 0 & 0 & 0 & 1 & 0 & 0 & 0 & 0 & 0 & 1 & 0 & 0 & 0 & 0 & 0 \\ 1 & 0 & 1 & 0 & 0 & 0 & 1 & 0 & 0 & 0 & 0 & 0 & 0 & 0 & 0 & 0 & 0 & 0 & 0 & 0 & 0 & 0 & 0 & 0 & 0 & 0 & 0 & 0 & 0 & 1 & 0 & 0 \\ 1 & 0 & 0 & 1 & 1 & 0 & 0 & 0 & 0 & 0 & 0 & 0 & 0 & 1 & 0 & 1 & 0 & 0 & 0 & 0 & 0 & 0 & 0 & 0 & 0 & 0 & 0 & 0 & 0 & 0 & 0 & 0 \\ 0 & 1 & 0 & 1 & 0 & 1 & 0 & 1 & 0 & 0 & 0 & 0 & 0 & 0 & 0 & 0 & 0 & 0 & 0 & 0 & 1 & 0 & 1 & 0 & 0 & 0 & 0 & 0 & 0 & 0 & 0 & 0 \\ 1 & 0 & 1 & 0 & 0 & 0 & 0 & 0 & 0 & 1 & 0 & 0 & 1 & 0 & 0 & 0 & 0 & 0 & 0 & 0 & 0 & 0 & 0 & 1 & 0 & 0 & 0 & 1 & 0 & 0 & 0 & 0 \\ 1 & 0 & 0 & 1 & 0 & 0 & 0 & 0 & 0 & 0 & 0 & 0 & 0 & 0 & 1 & 0 & 0 & 0 & 0 & 0 & 0 & 0 & 0 & 0 & 0 & 1 & 0 & 0 & 0 & 0 & 0 & 0 \\ 0 & 1 & 0 & 0 & 1 & 1 & 0 & 0 & 0 & 0 & 1 & 0 & 0 & 0 & 0 & 0 & 0 & 0 & 0 & 1 & 0 & 0 & 0 & 0 & 0 & 0 & 0 & 0 & 0 & 1 & 0 & 0 \\ 1 & 0 & 1 & 0 & 0 & 0 & 0 & 0 & 0 & 1 & 0 & 0 & 0 & 0 & 0 & 1 & 0 & 0 & 0 & 0 & 0 & 0 & 0 & 0 & 0 & 0 & 0 & 0 & 0 & 0 & 0 & 1 \\ 0 & 0 & 1 & 1 & 0 & 0 & 0 & 0 & 0 & 0 & 0 & 0 & 0 & 0 & 1 & 0 & 0 & 0 & 0 & 0 & 0 & 1 & 1 & 0 & 0 & 0 & 0 & 0 & 0 & 0 & 0 & 0 \\ 1 & 1 & 0 & 0 & 0 & 0 & 0 & 0 & 0 & 0 & 0 & 0 & 0 & 1 & 0 & 0 & 0 & 0 & 1 & 0 & 0 & 0 & 0 & 0 & 0 & 0 & 0 & 0 & 0 & 0 & 1 & 0 \\ 0 & 0 & 1 & 0 & 1 & 0 & 0 & 0 & 0 & 0 & 0 & 0 & 0 & 0 & 0 & 0 & 0 & 1 & 0 & 0 & 0 & 0 & 0 & 0 & 0 & 1 & 0 & 0 & 0 & 0 & 0 & 0 \\ 1 & 0 & 0 & 1 & 1 & 0 & 0 & 0 & 0 & 0 & 0 & 0 & 0 & 0 & 0 & 0 & 0 & 0 & 0 & 1 & 0 & 0 & 0 & 1 & 0 & 0 & 0 & 0 & 0 & 0 & 0 & 0 \\ 0 & 1 & 0 & 0 & 0 & 0 & 0 & 0 & 1 & 1 & 0 & 1 & 0 & 0 & 0 & 0 & 0 & 0 & 0 & 0 & 0 & 0 & 0 & 0 & 0 & 0 & 1 & 0 & 0 & 0 & 0 & 0 \\ 1 & 0 & 1 & 0 & 0 & 0 & 0 & 1 & 0 & 0 & 1 & 0 & 0 & 0 & 0 & 0 & 0 & 0 & 1 & 0 & 0 & 0 & 0 & 0 & 0 & 0 & 0 & 0 & 0 & 0 & 0 & 0 \\ 0 & 0 & 0 & 1 & 1 & 0 & 0 & 0 & 0 & 0 & 0 & 0 & 0 & 1 & 0 & 1 & 0 & 0 & 0 & 0 & 0 & 0 & 0 & 0 & 0 & 0 & 0 & 1 & 0 & 0 & 0 & 0 \\ 1 & 1 & 0 & 0 & 0 & 0 & 0 & 0 & 0 & 0 & 0 & 0 & 1 & 0 & 0 & 0 & 0 & 0 & 0 & 0 & 0 & 1 & 0 & 0 & 0 & 0 & 0 & 0 & 0 & 1 & 0 & 0 \\ 1 & 0 & 1 & 0 & 0 & 0 & 1 & 0 & 0 & 0 & 0 & 0 & 0 & 0 & 0 & 0 & 0 & 1 & 0 & 0 & 0 & 0 & 1 & 0 & 1 & 0 & 0 & 0 & 0 & 0 & 0 & 0 \\ 0 & 0 & 0 & 1 & 0 & 0 & 0 & 0 & 0 & 1 & 0 & 0 & 0 & 0 & 0 & 0 & 0 & 0 & 0 & 0 & 1 & 0 & 0 & 0 & 0 & 0 & 0 & 0 & 0 & 0 & 0 & 0 \\ 0 & 1 & 1 & 0 & 1 & 0 & 0 & 1 & 1 & 0 & 0 & 0 & 1 & 0 & 0 & 0 & 0 & 0 & 0 & 0 & 0 & 0 & 0 & 0 & 0 & 0 & 1 & 0 & 0 & 0 & 0 & 0 \\ 0 & 0 & 1 & 0 & 1 & 1 & 0 & 0 & 0 & 0 & 0 & 1 & 0 & 0 & 0 & 0 & 0 & 0 & 1 & 0 & 0 & 0 & 0 & 0 & 0 & 0 & 0 & 1 & 0 & 0 & 0 & 0\end{matrix} ] \qquad ( 16 )$$

In Equation (15), the component below the bar means Z^{A}(1:32,2:5)Z^{A}(1:32,1)Z^{A}(1:32,7:16)032×15, where Z^{A}(1:32,2:5) means submatrices obtained by extracting the 1st row to the 32nd row and the 2nd column to the 5th column in the matrix Z^{A}, and Z^{A}(1:32,1) represents submatrices obtained by extracting a 1st-column component from the 1st row to the 32nd row. Further, Z^{A}(1:32,7:16) represents submatrices obtained by extracting components from the 7th column to the 16th column in a range from the 1st row to the 32nd row.

Additionally, it should be noted that each mask matrix according to the encoding rate is used while shifting the submatrices of the mask matrix Z^{A} so that the same pattern may not be formed in a column direction. Specifically, the submatrices of the mask matrix Z^{A} are separated into submatrices with a heavy column degree (weight 14), and submatrices with light column degrees (weight is four or less), and are used while shifting each of them.

For example, Z^{A}(1:32,1:5) are the submatrices with the column degree 14 in the mask matrix Z^{A}, whereas in the mask matrix Z^{A(1/3)}, they are shifted to the left per column, and Z^{A}(1:32,2:5) Z^{A}(1:32,1) after the shift are coupled under Z^{A}(1:32,1:5) of the mask matrix Z^{A}.

Meanwhile, Z^{A}(1:32,6:32) are submatrices with four or less column degrees in the mask matrix Z^{A}, whereas in the mask matrix Z^{A(1/3)}, the submatrices Z^{A}(1:32,7:16) with the required number of columns are used among Z^{A}(1:32,6:32), and these Z^{A}(1:32,7:16) are couple under Z^{A}(1:32,6:15) of the mask matrix Z^{A}. As a result of this, small loops that are easy to be generated when H_{T} is used can be avoided.

The masking unit 22 outputs the irregular parity check matrix H_{M} using the mask matrix Z. The parity check matrix H_{M} can be represented as Equation (17) using, for example, the mask matrix Z with 64-row×32-column, the quasi-cyclic matrix H_{QCL} with 64 (row index j is 0 to 63)×32 (column index l is 0 to 31), and H_{T} with 64 (row index j is 0 to 63)×64 (column index l is 0 to 31).

H_{M}=[Z×H_{QC}|H_{T}]=[H_{MQC}|H_{T}] (17)

As explained above, the parity check matrix H_{MQC} for generating the LDPC codes C can be defined by determining the mask matrix Z and the cyclic permutation matrix at the row index j=0 of the quasi-cyclic matrix H_{QC} and giving the mask matrix Z to the parity check matrix.

The mask matrix Z corresponding to the encoding rate ⅓ can be determined by combining the submatrices of the mask matrix corresponding to the encoding rate ½, and thus there is no need to store a plurality of mask matrices to deal with different encoding rates. Namely, the storage capacity for storing the mask matrix can be reduced.

### Second Embodiment

The parity check-matrix generating method according to the first embodiment deals with the encoding rate ⅓, and can also deal with a case where the encoding rate is any other value. The parity check-matrix generating method for dealing with up to an encoding rate ⅕ will be explained below. It is noted that the configuration of the communication system is the same as that shown in FIG. 1, and how to configure the parity-check-matrix generator is the same as that as shown in FIG. 2.

Here, if the number of data bits is 32 and the encoding rate 23 is ⅕, the quasi-cyclic matrix H_{QC} is 128 (row index j is 0 to 127)×32 (column index l is 0 to 31). In this case, the masking unit 22 masks the quasi-cyclic matrix H_{QCL} with O-elements of the mask matrix Z with 128-row×32-column.

After the mask matrix Z is generated, the irregular parity check matrix H_{M} output from the masking unit 22 can be represented as Equation (18) using the mask matrix Z with 128-row×32-column, the quasi-cyclic matrix H_{QT} with 128×32, and H_{T} of 128 (row index j is 0 to 127)×128 (column index l is 0 to 127).

H_{M}=[Z×H_{QC}|H_{T}]=[H_{MQC}|H_{T]} (18)

It is noted that H_{T} of Equation (18) is given as Equation (19).

[Numerical Expression 12]

$${H}_{T} := [ \begin{matrix}{T}_{D} & 0 & 0 & 0 \\ I & I & 0 & 0 \\ 0 & I & I & 0 \\ 0 & 0 & I & I\end{matrix} ] \qquad ( 19 )$$

Further, T_{D} in H_{T} of Equation (19) is given as Equation (20).

[Numerical Expression 13]

$${T}_{D} := [ \begin{matrix}I ( 0 ) & 0 & 0 & ⋯ & 0 \\ I ( 0 ) & I ( 0 ) & 0 & ⋱ & ⋮ \\ 0 & I ( 0 ) & I ( 0 ) & ⋱ & ⋮ \\ ⋮ & ⋱ & ⋱ & ⋱ & ⋮ \\ 0 & ⋯ & 0 & I ( 0 ) & I ( 0 )\end{matrix} ] \qquad ( 20 )$$

Here, the irregular parity check matrix corresponding to the codes of the encoding rate ½ is represented as “H_{M(1/2)}=[Z^{A}×H_{QC(1/2)}|H_{T(1/2)}]”, where Z^{A}(=Z^{A(1/2)}) is a mask matrix with 32-row×32-column corresponding to the encoding rate ½ given by Equation (16). Further, H_{QC(1/2)} represents the quasi-cyclic matrix with 32 (row index j is 0 to 31)×32 (column index l is 0 to 31) of ¼ from the top in the quasi-cyclic matrix H_{QC}, H_{T(1/2)} is T_{D} given by Equation (20).

Similarly, the irregular parity check matrix is represented as H_{M(1/3)}, H_{M(1/4)}, and H_{M(1/5)} (=H_{M}) corresponding to encoding rates ⅓, ¼, and ⅕ respectively. Further, the mask matrix is represented as Z^{A(1/3)}, Z^{A(1/4)}, and Z^{A(1/5)} (=Z), and the quasi-cyclic matrix is represented as H_{QC(1/3)}, H_{QC(1/4)}, and H_{QC(1/5)} (=H_{QC}), and H_{T(1/3)}, H_{T(1/4)} and H_{T(1/5)} (=H_{T}).

The masking unit 22 according to the second embodiment masks H_{QCL} using the mask matrix Z shown by Equation (21).

[Numerical Expression 14]

$$Z = [ \frac{\frac{{Z}^{A}}{{Z}^{A} ( 1 \text{:} 32 , 2 \text{:} 5 ) {Z}^{A} ( 1 \text{:} 32 , 1 ) {Z}^{A} ( 1 \text{:} 32 , 7 \text{:} 16 ) {0}_{32 \times 15}}}{\frac{{Z}^{A} ( 1 \text{:} 32 , 3 \text{:} 5 ) {Z}^{A} ( 1 \text{:} 32 , 1 \text{:} 2 ) {Z}^{A} ( 1 \text{:} 32 , 8 \text{:} 17 ) {0}_{32 \times 15}}{{Z}^{A} ( 1 \text{:} 32 , 4 \text{:} 5 ) {Z}^{A} ( 1 \text{:} 32 , 1 \text{:} 3 ) {Z}^{A} ( 1 \text{:} 32 , 9 \text{:} 18 ) {0}_{32 \times 15}}} ] \qquad ( 21 )$$

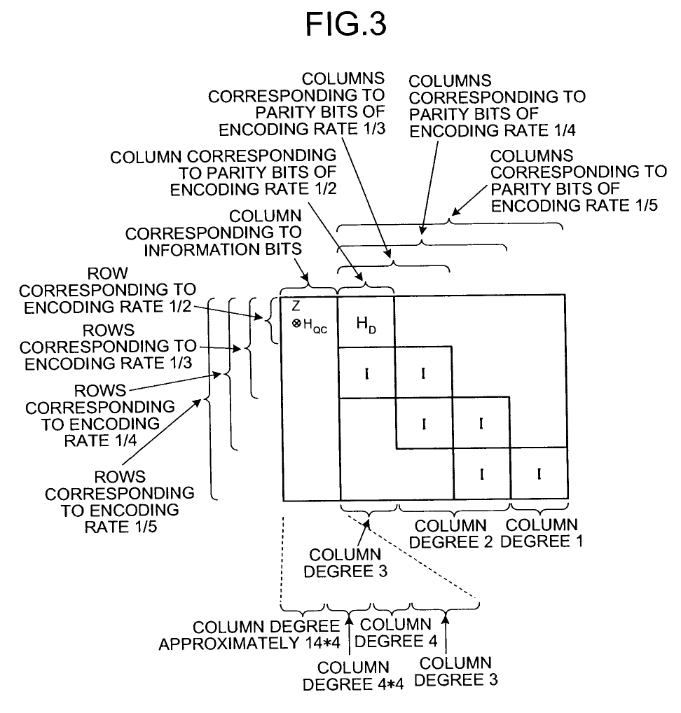

FIG. 3 is a view showing a configuration of the irregular parity check matrix H_{M} generated by being masked using the mask matrix Z.

In this manner, even the mask matrix Z (mask matrix Z^{A(1/5)}) corresponding to the encoding rate ⅕ is formed by using only the submatrices of the mask matrix Z^{A} corresponding to the encoding rate ½, and thus the memory capacity for storing the mask matrix can be reduced even when the mask matrix becomes large according to the encoding rate.

Similarly to the mask matrix corresponding to the encoding rate ⅓, in the case of the mask matrix corresponding to the encoding rate ⅕, the submatrices of the mask matrix Z^{A} are also used while being shifted so that the same pattern may not be formed in a column direction. Specifically, the submatrices of the mask matrix Z^{A} are separated into submatrices with a heavy column degree (weight 14) and submatrices with light column degrees (weight is four or less), and are used while each of them is shifted. Namely, for mask matrices Z^{A(1/4)} and Z^{A(1/5)}, the submatrices of the mask matrix Z^{A} are further used while being shifted under the submatrices shifted in the mask matrix Z^{A(1/3)}, so that the same pattern may not be formed in the column direction. Accordingly, small loops that are easy to be generated when H_{T} is used can be avoided.

### Third Embodiment

Subsequently, the configuration to set a lower limit of the encoding rate smaller than ⅙ will be explained below. In the communication system according to the first embodiment and the second embodiment, the lower limit of the encoding rate is desirably set to any value from ⅓ to ⅙. When the encoding rate equal to or less than the rate is to be achieved, achievement thereof using repeated transmission is more advantageous than the configuration based on the method mentioned in the first and the second embodiments because satisfactory performance is obtained.

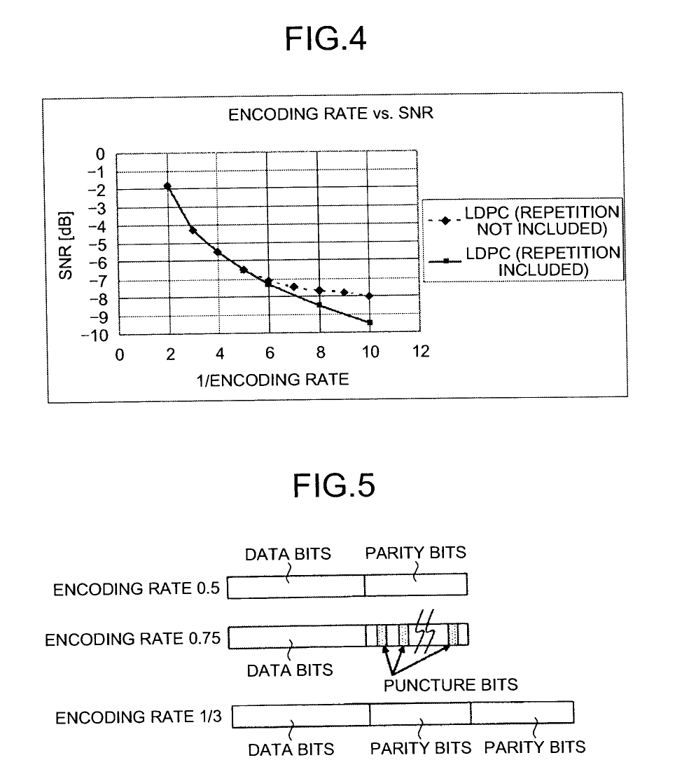

FIG. 4 represents the case where the encoding rate up to 1/10 is prepared using the code configuration method according to the first and the second embodiments, and also represents a case where the repeated transmission of a code explained hereinafter is used (the above-mentioned code is used when an encoding rate is up to ⅕, and the repeated transmission is used when an encoding rate is smaller than that). Note that the LDPC codes with a data length of 1312 bits are used as the code in FIG. 4. The communication channel is AWGN, and modulation is assumed to use the BPSK system.

The configuration as shown in FIG. 1 is also used for a transmission apparatus in the present embodiment. In the present embodiment, the configuration of the LPDC encoder 11 is different from that of the first and the second embodiments. The processing of the LPDC encoder 11 in a third embodiment will be explained next.

FIG. 5 is a view showing the code configuration method for the LPDC encoder 11. As is understood, in the LPDC encoder 11, codes of the encoding rate 0.5 are defined as a reference code, and parity is punctured in generating a code of an encoding rate (=0.75) higher than that. Incidentally, it is only necessary to insert zero in the reception LLR corresponding to puncturing bits by using the check matrix of the encoding rate ½ for decoding at this time, to then perform normal LDPC decoding.

Meanwhile, the LPDC encoder 11 adds parity in generating a code of the encoding rate (=⅓) lower than the reference code. In the LPDC decoder 15, only the submatrices of the check matrix HM corresponding to the encoding rate as shown in FIG. 3 are used to decode the code.

A construction method of the LDPC codes dealing with the encoding rates will be specifically explained here.

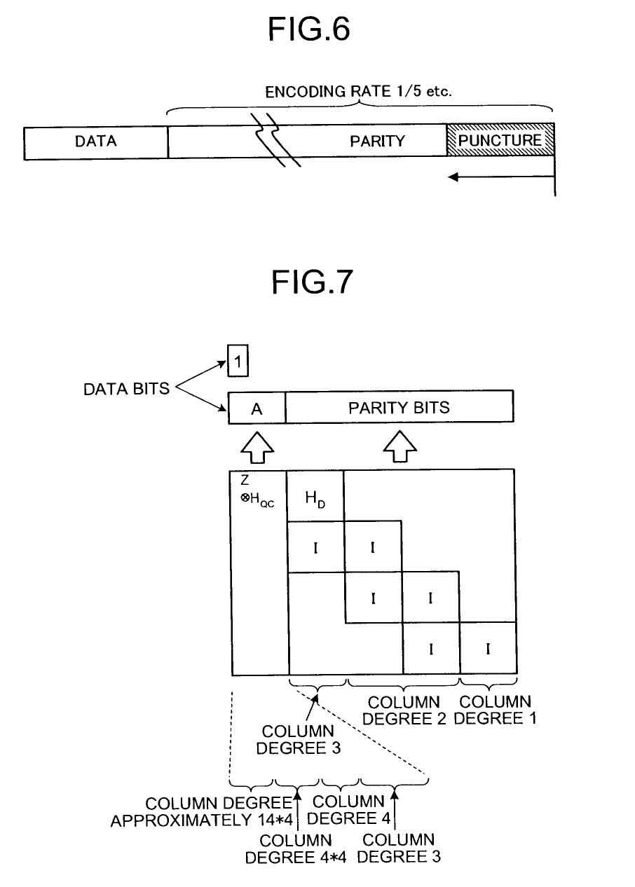

For example, it is supposed that the lowest encoding rate prepared by the system is R₀=⅓ or less. FIG. 6 is a view showing codes when the lowest encoding rate prepared by the system is R₀=⅕, for example.

For example, when the codes corresponding to the encoding rate R₀=⅕ are stored in the memory, and codes of an encoding rate R₁ are constructed, if the encoding rate R₁ is less than ½, namely, if the encoding rate R₁ is between ½ to ⅕, the parity bits are punctured from the end of the code in order.

Here, if an encoding rate of ⅕ or less is required, code bits B (length b: data of bits corresponding to each column is the same as A) selected in order of decreasing the column weight are added to a code (A+parity bits in FIG. 6) of an encoding rate K/N=⅕ based on the data length K and the code length N as shown in FIG. 7, so that the code of an encoding rate K/(N+b) can be generated. For example, if b=K, the encoding rate is ⅙, while if b=N, the encoding rate is 1/10.

As shown in the case of b=N, if all the codes are repeatedly transmitted twice and an encoding rate lower than the lowest encoding rate prepared by the system is required, code bits selected in order of decreasing the column weight are transmitted again, and the same operation is repeated. Accordingly, it is possible in principle to achieve any encoding rate no matter how low the encoding rate is.

The code v encoded by the method is received by the reception apparatus 3 through the communication channel, and if parts of or all of the code overlap when the LPDC decoder 15 corrects an error, received values of the overlapped bits are added by the number of the overlapped portions and are averaged, to then perform the processing of transferring the value to the LPDC decoder 15 for decoding.

As an effect of this method, it is known that the decoding performance becomes better when the reliability of the code bits corresponding to a column with a high weight is high (low error rate). Thus, the bits are repeatedly transmitted in order of decreasing the column weight, to perform the processing of reducing a distribution value of a noise component by the addition and averaging of the values in the reception side, and the reliability thereby increases (the error rate of the corresponding bits decreases), and thus the method has an effect of improving the decoding performance.

### Fourth Embodiment

In the communication systems according to the first to the third embodiments, if a size p of a regular (weights of the row and the column are uniform) quasi-cyclic matrix of p×p is set to be variable, an integer value obtained by rounding up K/r is selected for p when the data length K (the number of data bits) cannot be represented by p×r, and the known value “0” or “1” is sequentially inserted in bits corresponding to portions with the heavy column degree in the check matrix by the number of k-(integer obtained by rounding up K/r)×p, to be encoded, so that the values corresponding to the same bits in the check matrix may be determined as the known number “0” or “1”, to be decoded in the LPDC decoder 15 side.

This allows assignment of the most reliable known values (100% no error) as known data to the bits corresponding to the heavy column degree, and thus the method has an effect of improving the decoding performance.

### Fifth Embodiment

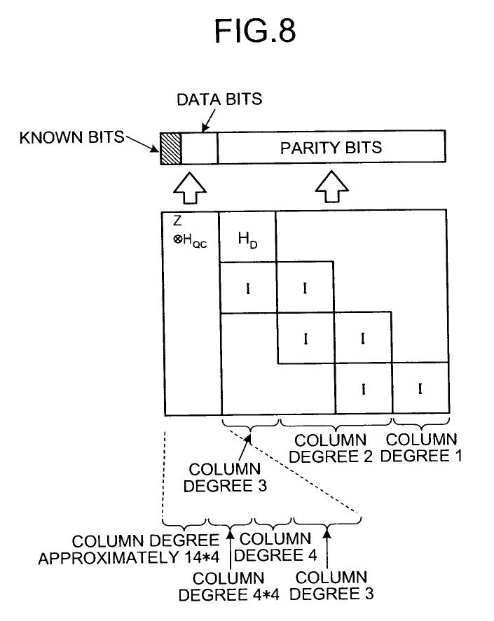

In the communication systems according to the first to the fourth embodiments, when the irregular (weights of the row and the column are nonuniform) parity check matrix is used to encode bits and a code with the code length N is generated, to prepare an encoding rate equal to or less than an encoding rate (N−M)/N which is decided by the number of rows M and the number of columns N of the parity check matrix, the known value “0” or “1” is inserted in bits in order of decreasing the column degree in the check matrix corresponding to the data bits as shown in FIG. 8, to be encoded, so that the values corresponding to the same bits in the check matrix are determined as the known number “0” or “1” and are decoded in the decoder side, which allows encoding decoding of the code of the low encoding rate. The code of the low encoding rate can be formed by using the method, and the most reliable known values (100% no error) as known data can be assigned to the bits corresponding to the heavy column degree, and thus the method has an effect of improving the decoding performance.

### Sixth Embodiment

In the fifth embodiment, to prepare the encoding rate equal to or less than the encoding rate (N−M)/N which is decided by the number of rows M and the number of columns N of the parity check matrix, the known numbers are assigned to the bits corresponding to columns with the heavy column degree, however, if there are too many known numbers, this may cause performance degradation. In this case, it is also possible to prepare the low encoding rate by the following method.

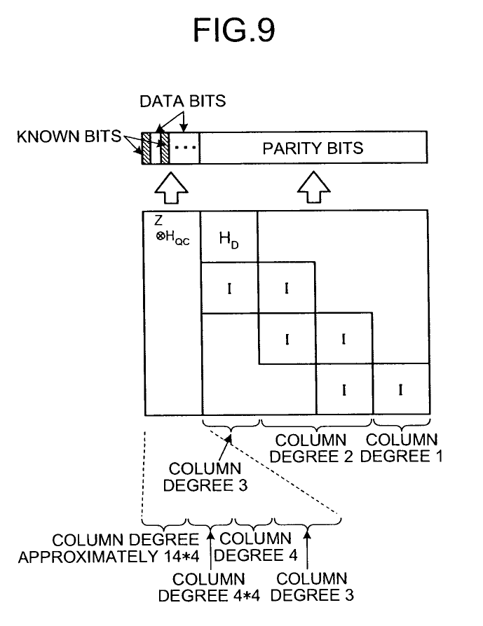

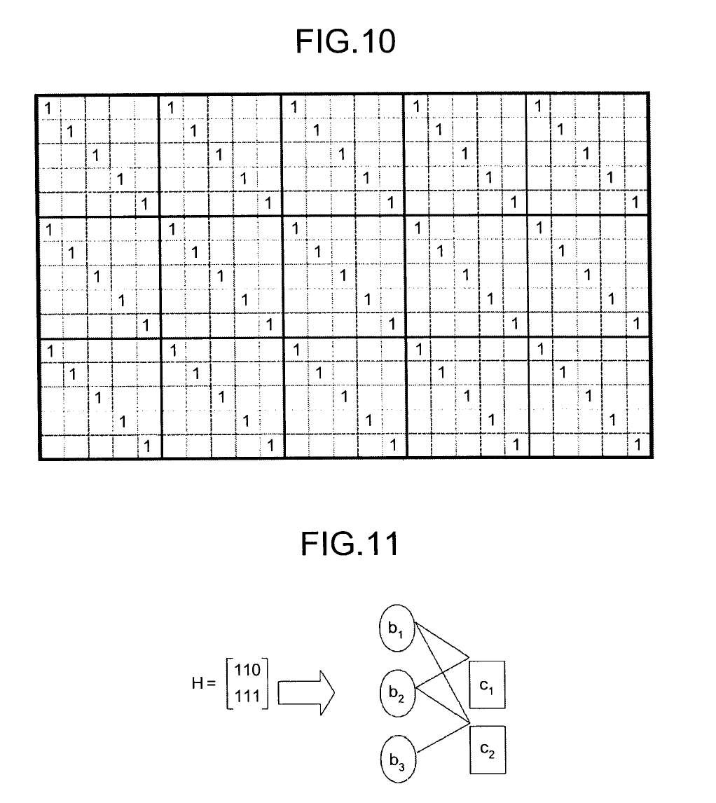

When the irregular (weights of the row and the column are nonuniform) parity check matrix is used to encode bits and a code with the code length N is generated, to prepare an encoding rate equal to or less than the encoding rate (N−M)/N which is decided by the number of rows M and the number of columns N of the parity check matrix, columns corresponding to the number of data bits smaller than N-M in the columns corresponding to the check matrix to which the data bits can be assigned are selected at approximate equal intervals as shown in FIG. 9, and the known value “0” or “1” is inserted in columns other than the columns and is encoded, while in the decoder side, the values corresponding to the known bits in the check matrix are determined as the known number “0” or “1” and are decoded, so that encoding/decoding is performed on the code of the low encoding rate.

For example, if the number of data bits is ½ of the number of columns corresponding to the data bits in a check matrix and an data bit sequence is u={u₁, u₂2, . . . , uₖ}, a data sequence u₀ inserted with the known number “0” becomes u₀={u₁, u₂, uₖ, 0}. In the code formed of the codes of the encoding rate ⅕, the encoding rate becomes 1/10 by this operation. Similarly, if the number of data bits is ⅓ of the number of columns corresponding to the data bits in a check matrix, degradation may not sometimes occur even if the known number is large.

This method enables the code of the low encoding rate to be prepared and degradation to be minimized even if the known number is large.

### INDUSTRIAL APPLICABILITY

The parity check-matrix generating method according to the present invention allows encoding corresponding to a wide range of encoding rates.

1. (canceled)

2. A method of generating a parity check matrix for a low-density parity check code, comprising:
generating a regular quasi-cyclic matrix in which cyclic permutation matrices are arranged in a row direction and a column direction and specific regularity is given to the cyclic permutation matrices;
obtaining an irregular parity check matrix having a low-density generation matrix structure in which a masking quasi-cyclic matrix and a matrix in which the cyclic permutation matrices are arranged in a staircase manner are arranged in a predetermined location;
generating a mask matrix capable of supporting a single encoding rate out of a plurality of encoding rates, for making the regular quasi-cyclic matrix into an irregular quasi-cyclic matrix; and
check-matrix generating including:
masking the irregular parity check matrix using a generated mask matrix, and
generating a parity check matrix in which a masked irregular parity check matrix is combined with a lower triangular matrix formed in a staircase manner to satisfy a single encoding rate.
